(19) United States
(12) Patent Application Publication
(10) Pub. No.: US 2004/0114653 A1
(43) Pub. Date: Jun. 17, 2004

(54) Surface emitting semiconductor laser and method of fabricating the same

(75) Inventor: Seiya Omori, Kanagawa (JP)

Correspondence Address: OLIFF & BERRIDGE, PLC, P.O. BOX 19928, ALEXANDRIA, VA, 22320, US

(73) Assignee: Fuji Xerox Co., Ltd., Tokyo (JP)

(21) Appl. No.: 10/639,645

(22) Filed: Aug. 13, 2003

(30) Foreign Application Priority Data
Dec. 16, 2002 (JP) 2002-363485

(51) Int. Cl. H01S 5/00; H01S 3/08

(52) U.S. Cl. 372/46; 372/96

(57) ABSTRACT

A surface emitting semiconductor laser includes a substrate, a laminate of semiconductor layers on the substrate, a mesa formed on the laminate and equipped with a laser emission window, and an insulation film that covers at least side and peripheral portions of the mesa, the peripheral portion of the mesa being provided by the laminate. Ends of the insulation film are located further in than cutoff ends of the substrate.

### BACKGROUND OF THE INVENTION

1. Field of the Invention

The present invention relates to a surface emitting semiconductor laser suitably used as sources for communication devices, measuring devices, optical recording devices and image forming apparatuses, and a method of fabricating the same.

2. Description of the Related Art

Recently, there has been an increased demand for a surface emitting semiconductor laser that can easily realize an arrangement of a two-dimensional array of sources in the technical fields of optical communications and optical recording. Such a surface emitting semiconductor laser is also called a vertical-cavity surface-emitting laser (VCSEL) The VCSEL has many advantages of a low threshold voltage, low power consumption, easy making of a circular spot of light and good productivity resulting from wafer-based evaluation.

FIG. 7A is a plan view of a conventional VCSEL chip, and FIG. 7B is a cross-sectional view taken along a line A-A shown in FIG. 7A. A VCSEL chip 100 has a GaAs substrate 105, and an n-side electrode 106 provided on the backside of the GaAs substrate 105. A post 101 having a cylindrical shape is provided on the front surface of the GaAs substrate 105. The post 101 may be formed by etching a laminate of semiconductor layers. After the post 101 is formed on the substrate 105, an interlayer insulation film 104 is formed so as to cover the post 101 and an exposed semiconductor layer (for example, an AlGaAs layer) that forms a peripheral portion of the post 101.

The post 101 may be called a post structure, mesa structure or pillar structure. An electrode pad 102 and an extraction interconnection 103 are formed on the interlayer insulation film 104. The extraction interconnection 103 is electrically connected to a p-side electrode within the post 101.

The VCSEL chip shown in FIGS. 7A and 7B has a relatively simple structure and may be produced by a simplified process. This brings about an advantage in cost. In contrast, if the VCSEL chip is placed in a high-temperature, high-humid circumstance without any hermetical seal, moisture absorption may shorten the lifetime and make the operation instable.

As to light-emitting devices that have a semiconductor layer containing Al that exhibits moisture absorption, several proposals about moisture proof or moisture resistance have been known. The proposals are primarily based on the use of a moisture-resistant layer for preventing water from invading. For example, Japanese Laid-Open Patent Application No. 2002-111054 discloses an InGaP moisture resistant layer, and Japanese Laid-Open Patent Application No. 11-87769 discloses a p-type GaAs surface protection film for controlling moisture absorption.

However, the conventional VCSEL shown in FIGS. 7A and 7B has the following disadvantages. First, due to moisture absorption of Al in the AlGaAs semiconductor layer that underlies the interlayer insulation film 104, the interlayer insulation film 104 may be removed from the underlying layer, and the post 101 may be left out from the substrate 105. Particularly, when the substrate 105 is subjected to dicing in a cutoff position indicated by a reference numeral 107, a gap may be caused in an interface portion 109 formed by the AlGaAs layer and the interlayer insulation film 104 due to stress resulting from the difference in thermal expansion coefficient therebetween. In such a case, removal of the interlayer insulation film 104 may be accelerated due to water invading via the interface portion 109. This may damage the electrode pad 102 and the extraction interconnection 103 on the interlayer insulation film 104, and a failure may be caused in operation.

Second, the VCSEL may step emitting light before or after the evaluation test. The VCSEL having the structure shown in FIGS. 7A and 7B has the interlayer insulation film that extends from the circumference of the post 101 to the entire upper surface of the chip. It is estimated that excessive internal stress in the interlayer insulation film may serve as one of the factors that cause the problems.

The aforementioned Japanese Laid-Open Patent Application No. 2002-111054 discloses the moisture-resistant layer applied to an LED that does not make laser oscillation, and Japanese Laid-Open Patent Application No. 11-87769 relates to an embedded type LED. The proposals disclosed in the above applications cannot be applied to the semiconductor laser having the post structure. It is to be noted that removal of the interlayer insulation film and internal stress caused therein as mentioned before are inherent in the semiconductor layer having the post structure or the mesa-type surface emitting semiconductor laser.

### SUMMARY OF THE INVENTION

The present invention has been made in view of the above circumstances and provides a surface emitting semiconductor laser.

According to an aspect of the present invention, there is provided a surface emitting semiconductor laser comprising: a substrate; a laminate of semiconductor layers on the substrate; a mesa formed on the laminate and equipped with a laser emission window; and an insulation film that covers at least side and peripheral portions of the mesa, the peripheral portion of the mesa being provided by the laminate, ends of the insulation film being located further in than cutoff ends of the substrate.

According to another aspect of the present invention, there is provided a surface emitting semiconductor laser comprising: a substrate; a laminate of semiconductor layers formed on the substrate; a mesa provided on the laminate and equipped with a laser emission window; and an insulation film that covers at least side and peripheral portions of the mesa, the peripheral portion of the mesa being provided by the laminate, the insulation film having a cutoff portion provided so as to surround a periphery of the mesa.

According to yet another aspect of the present invention, there is provided a surface emitting semiconductor laser comprising: a substrate; a laminate of semiconductor layers formed on the substrate; a mesa provided on the laminate and equipped with a laser emission window; and an insulation film that covers at least side and peripheral portions of the mesa, the peripheral portion of the mesa being provided by the laminate, a groove being formed in a part of the laminate, the insulation film being provided on an area including the groove.

According to a further aspect of the present invention, there is provided a method of fabricating a surface emitting semiconductor laser comprising the steps of: forming a laminate of semiconductor layers on a substrate; forming a mesa formed on the laminate and equipped with a laser emission window; forming an insulation film on the laminate and mesa; and removing a part of the insulation film so that the insulation film covers at least side and peripheral portions of the mesa, the peripheral portion of the mesa being provided by the laminate, ends of the insulation film being located further in than cutoff ends of the substrate.

According to a still further aspect of the present invention, there is provided a method of fabricating a surface emitting semiconductor laser comprising the steps of: forming a laminate of semiconductor layers on a substrate; forming a mesa formed on the laminate and equipped with a laser emission window; forming an insulation film on the laminate and mesa; and removing a part of the insulation film so that the insulation film covers at least side and peripheral portions of the mesa, the peripheral portion of the mesa being provided by the laminate, and surrounds the mesa.

According to another aspect of the present invention, there is provided a method of fabricating a surface emitting semiconductor laser comprising the steps of: forming a laminate of semiconductor layers on a substrate; forming a mesa formed on the laminate and equipped with a laser emission window; forming an insulation film on the laminate and mesa; and removing a part of the insulation film so that the insulation film covers at least side and peripheral portions of the mesa, the peripheral portion of the mesa being provided by the laminate, and has a cutoff portion.

According to still another object of the present invention, there is provided a method of fabricating a surface emitting semiconductor laser comprising the steps of: forming a laminate of semiconductor layers on a substrate; forming a mesa formed on the laminate and equipped with a laser emission window; forming a groove on the laminate; forming an insulation film on the laminate and mesa; and removing a part of the insulation film so that the insulation film covers at least side and peripheral portions of the mesa, the peripheral portion of the mesa being provided by the laminate.

### BRIEF DESCRIPTION OF THE DRAWINGS

Preferred embodiments of the present invention will be described in detail based on the following figures, wherein:

FIG. 1 is a cross-sectional view of a surface emitting semiconductor laser common to embodiments of the present invention described below;

FIG. 2A is a plan view of a surface emitting semiconductor laser according to a first embodiment of the present invention;

FIG. 2B is a cross-sectional view taken along a line B-B shown in FIG. 2A;

FIGS. 3A, 3B and 3C illustrate a method of producing the surface emitting semiconductor laser according to the first embodiment of the present invention;

FIG. 4A is a plan view of a surface emitting semiconductor laser according to a second embodiment of the present invention;

FIG. 4B is a cross-sectional view taken along a line C-C shown in FIG. 4A;

FIG. 5A is a plan view of a surface emitting semiconductor laser according to a third embodiment of the present invention;

FIG. 5B is a cross-sectional view taken along a line D-D shown in FIG. 5A;

FIG. 6A is a plan view of a device in which the chip according to the second embodiment of the present invention is die-mounted to a TO-type stem;

FIG. 6B is a cross-sectional view taken along a line E-E shown in FIG. 6A;

FIG. 7A is a plan view of a conventional surface emitting semiconductor laser; and

FIG. 7B is a cross-sectional view taken along a line A-A shown in FIG. 7A.

### DESCRIPTION OF THE PREFERRED EMBODIMENTS

A description will now be given of embodiments of the present invention with reference to the accompanying drawings.

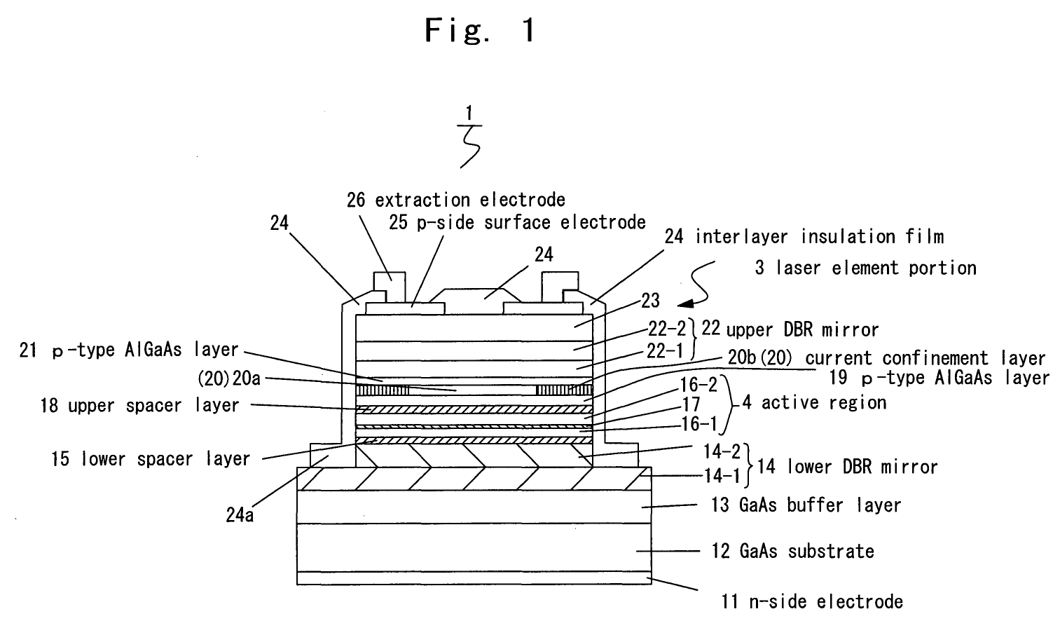

FIG. 1 is a cross-sectional view of a surface emitting semiconductor laser according to an embodiment of the present invention. The cross section shown in FIG. 1 is common to other embodiments of the present invention that will be described later. The basic structure of the surface emitting semiconductor laser shown in FIG. 1 common to all the embodiments described below will be described first, and a description of the individual embodiments will be described second.

The surface emitting semiconductor laser shown in FIG. 1 is a selective oxidization type surface emitting semiconductor laser equipped with a laser element portion 3 having a cylindrical mesa structure (which may be called a post structure or pillar structure). For the sake of simplicity, a protection film provided on the mesa structure and a bonding pad portion extending from a metal contact layer are omitted from FIG. 1.

The laser includes an n-type GaAs substrate 12, and an n-type GaAs buffer layer 13 formed thereon. A layer 11 provided on the backside of the substrate 12 is an n-side electrode. A layer 14 on the buffer layer 13 is an n-type lower DBR (Distributed Bragg Reflector) of the resonator. The n-type lower DBR layer 14 has multiple first lower mirror layers 14-1 and second lower mirror layers 14-2 having a different composition ratio. It is to be noted that FIG. 1 schematically shows the first mirror layers 14-1 and the second mirror layers 14-2.

On the lower mirror layer 14, provided are a lower spacer layer 15, an active region 4 and an upper spacer layer 18. The active region 4 includes an undoped lower barrier layer 16-1, an undoped quantum well layer 17, and an undoped upper barrier layer 16-2. An upper spacer layer 18 is provided on the active region 4. On the upper spacer layer 18, provided are a p-type AlGaAs layer 19, a p-type AlAs layer 20, and a p-type AlGaAs layer 21. The AlAs layer 20 is a current confining layer, which includes an AlAs portion 20a and an oxide region 20b. The AlAs portion 20a defines a circular aperture in the center of the AlAs layer 20. The oxide region 20b is a selectively oxidized region around the AlAs portion 20a. The current confinement layer confines current and light that pass therethrough. The AlGaAs layers 19 and 21 provided on the lower and upper sides of the current confinement layer 20 serve as buffer layers, which match the lattice constants to relax distortion. The buffer layers mentioned above may be omitted.

A p-type upper DBR mirror layer 22 is provided above the resonator. The upper DBR mirror layer 22 has multiple first upper mirror layers 22-1 and second upper mirror layers 22-2 that are alternately laminated. In FIG. 1, these mirror layers are schematically depicted. A p-type contact layer 23, an interlayer insulation film 24, and a p-side electrode 25 are provided. The p-side electrode 25 has a ring shape that defines a laser emission window on the contact layer 23. An extraction wire portion or interconnection 26 is connected to the p-side electrode 25.

The interlayer insulation film 24 of the present surface emitting semiconductor laser has a unique shape. The interlayer insulation film 24 covers an edge portion of the upper surface of the mesa structure, the side surface thereof and a mesa peripheral portion. The mesa peripheral portion corresponds to a region extending outwards from the base portion on which the mesa 3 is formed. In the structure shown in FIG. 1, the mesa peripheral portion corresponds to a region 24a provided on the lower mirror layer 14. Conventionally, the interlayer insulation layer is provided so as to cover the entire surface of the substrate up to the dicing surfaces thereof. The interlayer insulation film 24 quite differs in shape from that of the conventional arrangement.

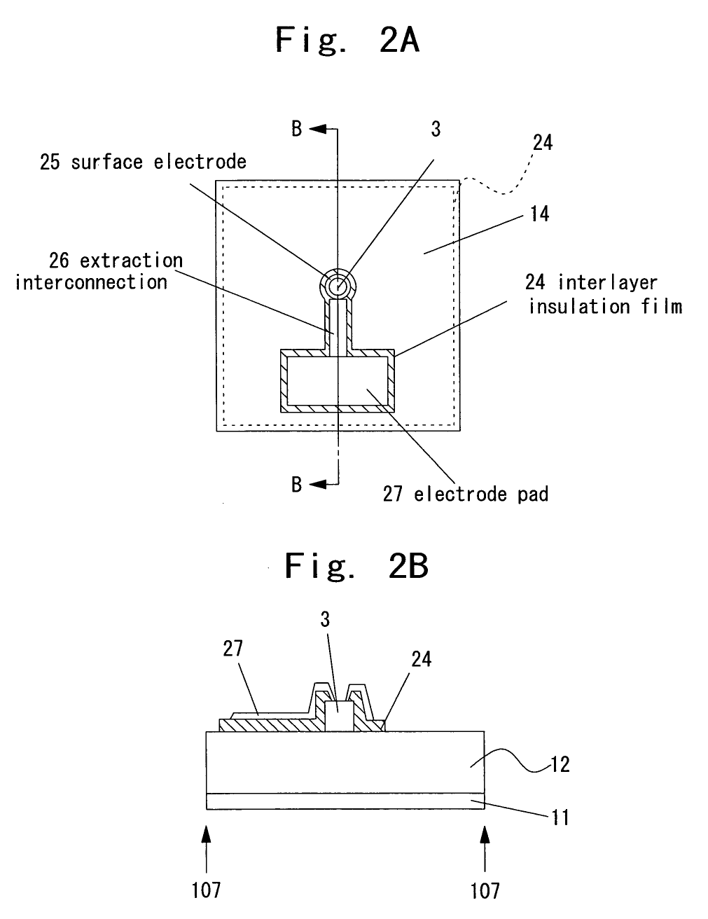

Now, first through third embodiments of the present invention will be described. FIG. 2A is a plan view of a chip of a surface emitting semiconductor laser according to a first embodiment of the present invention, and FIG. 2B is a cross-sectional view taken along a line B-B shown in FIG. 2A. The lower mirror layer 14 provided on the substrate 12 is omitted in FIG. 2B for the sake of simplicity.

The edges of the interlayer insulation film 24 are located further in than the dicing surfaces 107 that define the four outside ends of the chip. Particularly, according to the present embodiment, the ends of the interlayer insulation film 24 are set back (offset) from the dicing surfaces so as to have a shape that corresponds to the outer shapes of the laser element portion (mesa structure) 3, the extraction interconnection 26 and the electrode pad 27.

The interlayer insulation film 24 thus designed makes it possible to prevent an end portion of the interlayer insulation film 24 from being removed from the surface of the semiconductor layer (the lower mirror layer 14) because mechanical stress caused by the dicing blade is not applied directly to the interlayer insulation film 24. In the example shown in FIGS. 2A and 2B, the end portions of the interlayer insulation film 24 are greatly set back and are close to the outer ends of the laser element portion 3, the extraction interconnection 26 and the electrode pad 27. Thus, the interlayer insulation film 24 has a much smaller than that of the conventional interlayer insulation film 24. Thus, the interlayer insulation film 24 has very much reduced internal stress caused due to the difference in the thermal expansion coefficient between the lower mirror layer 14 and the interlayer insulation film 24. According to the present embodiment of the invention, it is possible to prevent removal of the interlayer insulation film 24 and reduce the internal stress caused therein and to realize stable laser emission and longer lifetime.

In the first embodiment of the present invention, both removal of the interlayer insulation layer 24 and reduction in the internal stress are simultaneously realized. Alternatively, the interlayer insulation film 24 may have a pattern as indicated by the broken line shown in FIG. 2A. Only by slightly setting back the ends of the interlayer insulation film 24 from the dicing surfaces 107, there are no interfaces between the interlayer insulation film 24 and the lower mirror layer 14 on the dicing surfaces 107. It is thus possible to solve the problem of removal of the interlayer insulation film 24. The degree of setback may be appropriately chosen taking the process width of the blade at the time of dicing.

In short, the surface emitting semiconductor laser shown in FIGS. 2A and 2B includes the substrate 12, the laminate of semiconductor layers 13 and 14 on the substrate 12, a mesa formed on the laminate and equipped with the laser emission window 20a, and the insulation film 24 that covers at least side and peripheral portions of the mesa, the peripheral portion of the mesa being provided by the laminate. The ends of the insulation film 24 are located further in than cutoff ends of the substrate. Thus, there are no interfaces between the insulation film 24 and the semiconductor layer 14-1 on the cutoff surfaces of the substrate. It is therefore possible to prevent water or the like from invading from the interface and the insulation film 24 from being removed. The simple arrangement of the insulation film 24 so that the ends thereof are located further in than the dicing surfaces of the substrate realizes difficulty in removal of the insulation film 24. Preferably, the ends of the insulation film are located close to the periphery of the mesa. That is, the insulation film 24 has an extremely reduced area, so that there is a very small possibility that water invades from the ends of the insulation film 24.

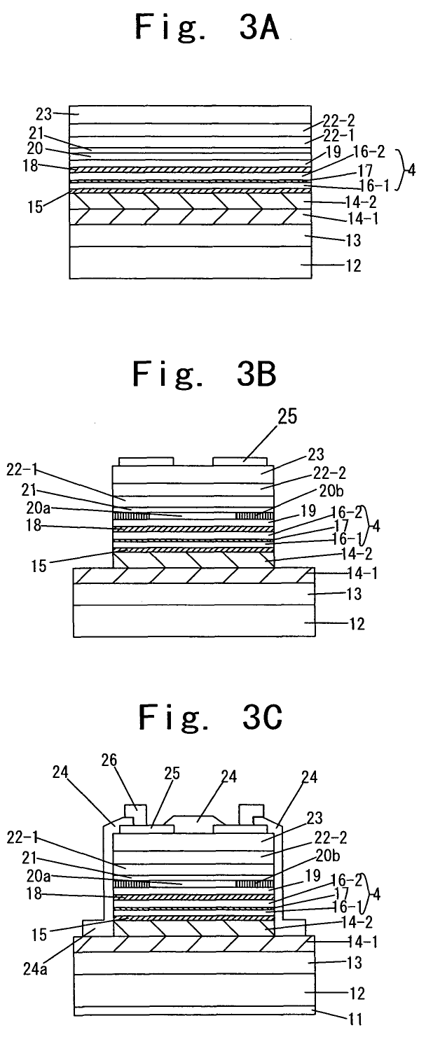

A description will now be given, with reference to FIGS. 3A through 3C, of a method of fabricating the surface emitting semiconductor laser according to the first embodiment of the present invention. Referring to FIG. 3A, the n-type GaAs buffer layer 13 is deposited on the n-type GaAs substrate 12 by MOCVD (Metal Organic Chemical Vapor Deposition). The n-type lower DBR mirror layer 14, which forms the lower part of the resonator, is laminated on the buffer layer 13. The lower DBR mirror layer 14 may be formed by the first mirror layer 14-1 of, for example, Al_{0.9}Ga_{0.1}As and the second mirror layer 14-2 of, for example, Al_{0.3}Ga_{0.7}As, which are alternately laminated by 40.5 periods.

The lower spacer layer 15 of Al_{0.6}Ga_{0.4}As is deposited on the lower mirror layer 14. The undoped quantum well layer 19 of Al_{0.12}Ga_{0.88}As is deposited to a thickness of 9 nm on the lower spacer layer 15. The barrier layers 16-1 and 16-2 of Al_{0.3}Ga_{0.7}As are respectively deposited to a thickness of 5 nm on the lower and upper surfaces of the quantum well layer 17. In this manner, the quantum well active region 4 can be defined. The upper spacer layer 18 of Al_{0.6}Ga_{0.4}As is deposited on the active region 4. Then, the p-type Al_{0.9}Ga_{0.1}As layer 19, the p-type AlAs layer 20 and the p-type Al_{0.9}Ga_{0.1}As layer 21 are laminated in this order on the upper spacer layer 18.

The upper DBR mirror layer 22 that forms the upper part of the resonator is formed on the p-type Al_{0.9}Ga_{0.1}As layer 21. The upper DBR mirror layer 22 may be formed by the first mirror layer 22-1 of Al_{0.3}Ga_{0.7}As and the second mirror layer 22-2 of AlAs, which are alternately laminated to a thickness equal to 24 periods. The contact layer 23 of p-type GaAs is deposited on the upper DBR mirror layer 22, and the epitaxial growth process is finished (FIG. 3A).

Next, as shown in FIG. 3B, the p-side electrode 25 is formed by sputtering or vapor deposition and is photolithographically patterned to form the emission window. Then, resist is photolithographically patterned, and the wafer is processed by RIE wherein the patterned resist serves as mask. This results in the mesa structure. The above etching is required to go beyond at least the AlAs layer 20, and is preferably performed until the lower mirror layer 14 is exposed. After the mesa structure is formed, the substrate 12 or wafer is exposed to high-temperature oxygen in a furnace for a given time, so that the AlAs layer 20 can be oxidized from the side surface of the mesa and the current confinement layer can be defined.

As shown in FIG. 3C, the interlayer insulation film 24 is uniformly provided over the wafer by sputtering or plasma-assisted CVD. The interlayer insulation film 24 may be a single layer of SiNx or SiON, or a laminate that contains the both layers. A patterned resist is photolithographically formed and the unnecessary portion of the interlayer insulation film 24 is removed by etching. As shown in FIGS. 2A and 2B, the interlayer insulation film 24 is processed on the periphery of the mesa so as to have a shape that corresponds to the shapes of the laser element portion 3, the extraction interconnection 26 and the electrode pad 27. Simultaneously, on the surface of the mesa, a contact hole for making a contact with the p-side electrode 25 is formed.

Then, a laminate of Ti/Au is deposited and is then formed into the extraction interconnection 26 and the electrode pad 27 by the liftoff process. Thereafter, the wafer is subjected to provisional dicing, and the back surface of the wafer is polished. Then, a laminate of Au/AuGe for the n-side electrode 11 is deposited on the back surface of the wafer (n-type GaAs substrate 12), and the wafer is finally divided into the individual chips by dicing. In this manner, the individual chips each having the structure shown in FIGS. 2A and 2B can be produced.

As described above, according to the first embodiment of the present invention, it is possible to prevent removal of the interlayer insulation film and reduce the internal stress caused therein by simply modifying the conventional fabrication process so as to form the interlayer insulation film 24 into a given shape by etching.

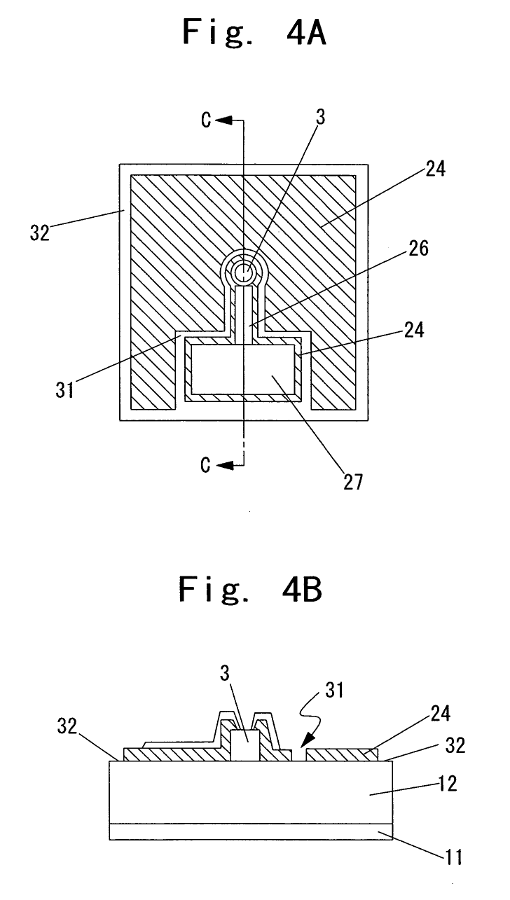

FIGS. 4A and 4B show a chip of a surface emitting semiconductor laser according to a second embodiment of the present invention. More particularly, FIG. 4A is a plan view of the chip, and FIG. 4B is a cross-sectional view taken along a line C-C shown in FIG. 4A. The interlayer insulation film 24 employed in the present embodiment is set back by a distance 32 from the four ends (cutoff surfaces) of the chip within which chipping does not reach. Further, a cut is made in the interlayer insulation film 24 in the vicinity of the cylindrical laser element portion (mesa structure) 3, the extraction interconnection 26 and the electrode pad 27. In FIG. 4A, the hatched areas correspond to the interlayer insulation film.

According to the present embodiment, the setback ends of the interlayer insulation film 24 prevent removal thereof on a dicing surface and inhibit removal from further advancing even if the interlayer insulation film 24 is removed from the dicing surface. The cut portion 31 separates a first part of the interlayer insulation film 24 close to the laser element portion 3 from a second part thereof located further out than the first part. This separation prevents internal stress caused in the first and second parts of the film 24 from interfering each other and prevents internal stress caused in one of the first and second parts from being applied to the other. According to the second embodiment of the invention, it is possible to prevent removal of the interlayer insulation film 24 and reduce the internal stress caused therein and to realize stable laser emission and longer lifetime.

If it is desired to reduce stress in the interlayer insulation film 24 that develops due to the structure of the laser element portion 3, the cut portion may be provided only in the vicinity of the laser element portion 3.

In short, according to the second embodiment of the present invention, the surface emitting semiconductor laser includes the substrate 12, the laminate of semiconductor layers 13 and 14 formed on the substrate 12, a mesa provided on the laminate and equipped with a laser emission window 20a, and an insulation film 24 that covers at least side and peripheral portions of the mesa, the peripheral portion of the mesa being provided by the laminate. The insulation film 24 has a cut portion 31 provided so as to surround a periphery of the mesa. With this arrangement, the insulation film 24 is divided into parts, so that internal stress in the insulation film 24 can be distributed and reduced. Internal stress in one of the divided parts of the insulation film 24 is not applied to another divided part. The divided parts of the insulation film 24 are not required to be isolated from one another, but may be partially connected as long as the influence of internal stress from one to another is suppressed.

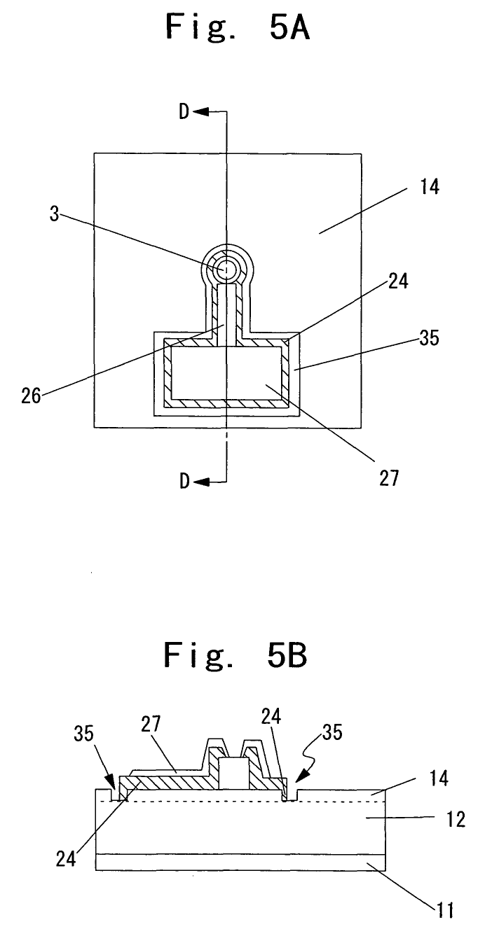

FIGS. 5A and 5B show a chip of a surface emitting semiconductor laser according to a third embodiment of the present invention. More particularly, FIG. 5A is a plan view of the chip, and FIG. 5B is a cross-sectional view taken along a line D-D. According to the third embodiment, a groove 35 is provided on the lower mirror layer 14 on the substrate so as to surround the mesa 3. The end portions of the interlayer insulation film 24 are formed in an area that includes the groove 35. The end portions of the interlayer insulation film 24 may stop within the groove 35.

With the above-mentioned structure, the contacting area between the interlayer insulation film 24 and the underlying semiconductor layer can be increased, so that the contacting force can be enhanced and removal of the film 24 can be prevented. The groove 35 is provided in the vicinity of the laser element portion (mesa) 3, the extraction interconnection 26 and the electrode pad 27 and is shaped along the shapes thereof. Thus, even if excessive stress is developed in the interlayer insulation film 24 due to the shapes and materials of the laser element portion 3, the extraction interconnection 26 and the electrode pad 27, it is possible to prevent removal and degradation of the interlayer insulation film 24. If it is only desired to prevent removal of the interlayer insulation film 24, the groove 35 may be provided in the vicinity of the four sides of the chip.

In FIGS. 5A and 5B, the groove 35 is continuously provided, and accommodates the ends of the interlayer insulation film 35. Alternatively, the groove 35 may be formed discontinuously. In FIGS. 5A and 5B, the interlayer insulation film 24 remains in the vicinity of the periphery of the laser element portion 3. Alternatively, the interlayer insulation film 24 may be provided on an extended region that includes the groove 35. Preferably, the interlayer insulation film 24 may stop short of the dicing surfaces.

The laser device of the third embodiment of the present invention may be produced by forming the groove 35 on the lower mirror layer 14 that has been exposed by forming the mesa 3. The groove 35 may be formed by dry etching or chemical etching. For example, when sulfuric-acid based chemical etching is employed, the groove 35 that does not have any steep step can be formed. The post process may be the same as that of the first embodiment of the present invention. That is, the interlayer insulation film 24 is uniformly deposited by sputtering or plasma-assisted CVD and is photolithographically patterned by etching.

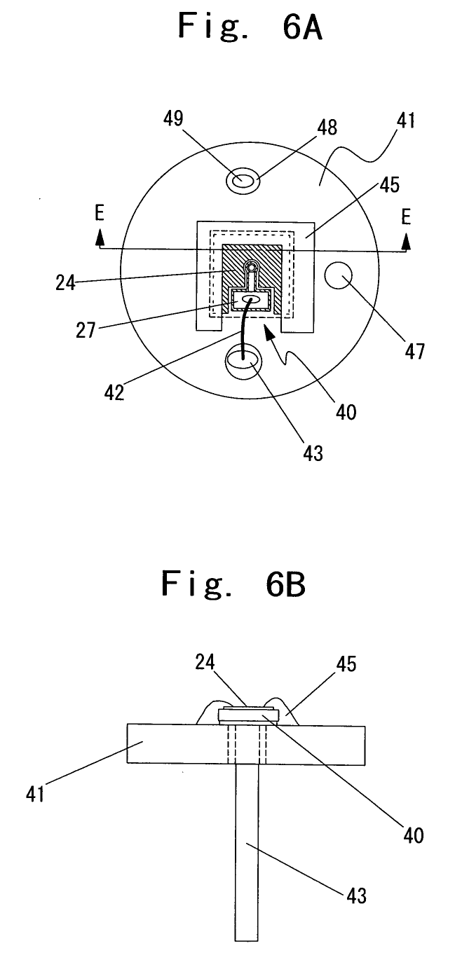

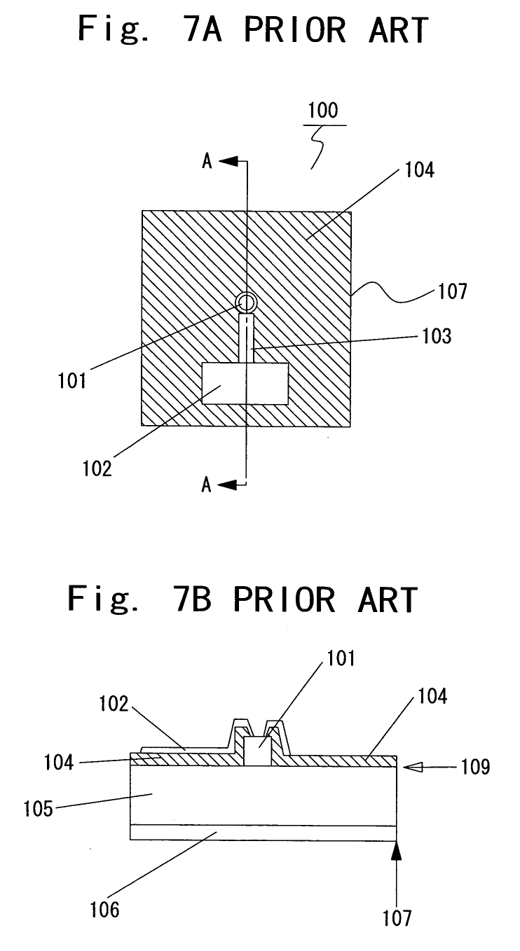

FIGS. 6A and 6B show a device that has a TO-tube type stem 41 on which the chip according to the second embodiment of the invention shown in FIGS. 4A and 4B is mounted. More particularly, FIG. 6A is a plan view of the device in which the chip is die-mounted, and FIG. 6B is a cross-sectional view taken along a line E-E shown in FIG. 6A. As has been described, partial removal of the interlayer insulation film 24 results in an exposed portion of the semiconductor layer that is not coated with the interlayer insulation film. It is therefore necessary to protect the exposed portion from atmospheric air.

Taking the above into consideration, an exposed portion of a chip 40 that is not coated with the interlayer insulation film 40 is coated with a mold resin 45. The exposed portion of the chip resulting from the setback arrangement of the interlayer insulation film 24 is protected by the mold resin 45. The mold resin 45 functions to prevent water from invading from the exposed portion that is not coated with the interlayer insulation film 24 and to thus improve moisture resistance.

The structure shown in FIGS. 6A and 6B can be produced as follows. An electrically conductive adhesive agent of thermosetting type is provided on the metal stem 41 of TO-tube type, and the chip 40 is mounted in a given position with a pressure being applied thereto by means of a mounter. The stem 41 with the chip 40 being mounted thereon is put in an oven, and the conductive adhesive is thermally cured. The conductive adhesive may be an Ag-based epoxy adhesive. Instead of such an adhesive, In solder, Pb-based solder foil, AuSn-based composition solder.

Then, the thermosetting mold resin 45 is provided and cured by a coating machine. The mold resin 45 may be epoxy adhesive of cold cure type. Alternatively, it is possible to use a polyimide-based material or silicone-based material. The electrode pad 27 on the chip side and an external lead wire 43 are connected by a bonding wire 42. An area that is not coated with mold resin is provided on the chip 40 in order to prevent the capillary of the wire from touching the mold resin. The area coated with mold resin may be appropriately adjusted within the range in which the height of mold and movement of the capillary can be adjusted. After this adjustment, a cap for sealing may be provided. In FIGS. 6A and 6B, a reference numeral 47 indicates a lead wire for ground, and is electrically connected to the n-side electrode of the chip 40 via the metal stem 41.

In the foregoing description of FIGS. 6A and 6B, the portion from which the interlayer insulation film has been removed is coated with resin for protection. Alternatively, a protection film of, for example, polyimide may be provided on the chip.

The present invention is not limited to the specifically disclosed embodiments, and variations and modifications may be made without departing from the scope of the present invention.

According to the present invention, the insulation film that covers the side and peripheral portions of the mesa ends further in than the cutoff ends of the substrate. This makes it possible to suppress the insulation film from being removed from the substrate or the underlying semiconductor layer and to thus prevent the mesa from being left out from the substrate and prevent the electrode interconnection from being broken. It is therefore possible to stabilize the operation of the surface emitting semiconductor laser and improve the lifetime thereof. Further, the cutoff portion provided in the insulation film relaxes internal stress in the insulation film and prevents degradation thereof. This also contributes to lengthening the lifetime of the surface emitting semiconductor laser.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A surface emitting semiconductor laser comprising:
a substrate;
a laminate of semiconductor layers on the substrate;
a mesa formed on the laminate and equipped with a laser emission window; and
an insulation film that covers at least side and peripheral portions of the mesa, the peripheral portion of the mesa being provided by the laminate,
ends of the insulation film being located further in than cutoff ends of the substrate.

2. The surface emitting semiconductor laser as claimed in claim 1, wherein the cutoff ends are dicing surfaces.

3. The surface emitting semiconductor laser as claimed in claim 1, wherein:
the cutoff ends are dicing surfaces; and
the ends of the insulation film are inwards set back from the dicing surfaces.

4. The surface emitting semiconductor laser as claimed in claim 1, wherein the ends of the insulation film have a shape that corresponds to an outer shape of the mesa.

5. The surface emitting semiconductor laser as claimed in claim 1, wherein:
the mesa includes an electrode that defines the laser emission window and receive current;
an electrode pad that is electrically connected to the electrode and extends from the electrode is provided on the insulation film on the peripheral portion of the mesa; and
the ends of the insulation film have a shape that corresponds to an outer shape of the electrode.

6. A surface emitting semiconductor laser comprising:
a substrate;
a laminate of semiconductor layers formed on the substrate;
a mesa provided on the laminate and equipped with a laser emission window; and
an insulation film that covers at least side and peripheral portions of the mesa, the peripheral portion of the mesa being provided by the laminate,
the insulation film having a cut portion provided so as to surround a periphery of the mesa.

7. The surface emitting semiconductor laser as claimed in claim 6, wherein the ends of the insulation film have a shape that corresponds to an outer shape of the mesa.

8. The surface emitting semiconductor laser as claimed in claim 6, wherein:
the mesa includes an electrode that defines the laser emission window and receive current;
an electrode pad that is electrically connected to the electrode and extends from the electrode is provided on the insulation film on the peripheral portion of the mesa; and
the ends of the insulation film have a shape that corresponds to an outer shape of the electrode.

9. A surface emitting semiconductor laser comprising:
a substrate;
a laminate of semiconductor layers formed on the substrate;
a mesa provided on the laminate and equipped with a laser emission window; and
an insulation film that covers at least side and peripheral portions of the mesa, the peripheral portion of the mesa being provided by the laminate,
a groove being formed in a part of the laminate,
the insulation film being provided on an area including the groove.

10. The surface emitting semiconductor laser as claimed in claim 9, wherein the ends of the insulation film have a shape that corresponds to an outer shape of the mesa.

11. The surface emitting semiconductor laser as claimed in claim 9, wherein:
the mesa includes an electrode that defines the laser emission window and receive current;
an electrode pad that is electrically connected to the electrode and extends from the electrode is provided on the insulation film on the peripheral portion of the mesa; and
the ends of the insulation film have a shape that corresponds to an outer shape of the electrode.

12. The surface emitting semiconductor laser as claimed in claim 1, wherein the laminate includes a semiconductor layer containing aluminum on which the insulation film is provided.

13. The surface emitting semiconductor laser as claimed in claim 6, wherein the laminate includes a semiconductor layer containing aluminum on which the insulation film is provided.

14. The surface emitting semiconductor laser as claimed in claim 9, wherein the laminate includes a semiconductor layer containing aluminum on which the insulation film is provided.

15. The surface emitting semiconductor laser as claimed in claim 1, wherein:
the laminate includes a semiconductor layer containing aluminum on which the insulation film is provided;
the semiconductor layer containing aluminum is a part of a semiconductor mirror of a first conduction type having a semiconductor multilayer structure, and contains a composition of AlGaAs.

16. The surface emitting semiconductor laser as claimed in claim 6, wherein:
the laminate includes a semiconductor layer containing aluminum on which the insulation film is provided;
the semiconductor layer containing aluminum is a part of a semiconductor mirror of a first conduction type having a semiconductor multilayer structure, and contains a composition of AlGaAs.

17. The surface emitting semiconductor laser as claimed in claim 9, wherein:
the laminate includes a semiconductor layer containing aluminum on which the insulation film is provided;
the semiconductor layer containing aluminum is a part of a semiconductor mirror of a first conduction type having a semiconductor multilayer structure, and contains a composition of AlGaAs.

18. The surface emitting semiconductor laser as claimed in claim 1, wherein the mesa comprises at least an active region, a current confinement layer containing a selectively oxidized region, and a semiconductor mirror having a conduction type different from that of another mirror formed by the laminate.

19. The surface emitting semiconductor laser as claimed in claim 6, wherein the mesa comprises at least an active region, a current confinement layer containing a selectively oxidized region, and a semiconductor mirror having a conduction type different from that of another mirror formed by the laminate.

20. The surface emitting semiconductor laser as claimed in claim 9, wherein the mesa comprises at least an active region, a current confinement layer containing a selectively oxidized region, and a semiconductor mirror having a conduction type different from that of another mirror formed by the laminate.

21. A method of fabricating a surface emitting semiconductor laser comprising the steps of:
forming a laminate of semiconductor layers on a substrate;
forming a mesa formed on the laminate and equipped with a laser emission window;
forming an insulation film on the laminate and mesa; and
removing a part of the insulation film so that the insulation film covers at least side and peripheral portions of the mesa, the peripheral portion of the mesa being provided by the laminate,
ends of the insulation film being located further in than cutoff ends of the substrate.

22. The method as claimed in claim 21, further comprising a step of cutting the semiconductor substrate into chips, ends of the chips being defined by cutting.

23. A method of fabricating a surface emitting semiconductor laser comprising the steps of:
forming a laminate of semiconductor layers on a substrate;
forming a mesa formed on the laminate and equipped with a laser emission window;
forming an insulation film on the laminate and mesa; and
removing a part of the insulation film so that the insulation film covers at least side and peripheral portions of the mesa, the peripheral portion of the mesa being provided by the laminate, and surrounds the mesa.

24. A method of fabricating a surface emitting semiconductor laser comprising the steps of:
forming a laminate of semiconductor layers on a substrate;
forming a mesa formed on the laminate and equipped with a laser emission window;
forming an insulation film on the laminate and mesa; and
removing a part of the insulation film so that the insulation film covers at least side and peripheral portions of the mesa, the peripheral portion of the mesa being provided by the laminate, and has a cut portion.

25. A method of fabricating a surface emitting semiconductor laser comprising the steps of:
forming a laminate of semiconductor layers on a substrate;
forming a mesa formed on the laminate and equipped with a laser emission window;
forming a groove on the laminate;
forming an insulation film on the laminate and mesa; and
removing a part of the insulation film so that the insulation film covers at least side and peripheral portions of the mesa, the peripheral portion of the mesa being provided by the laminate.

26. The method as claimed in claim 25, further comprising a step of patterning the insulation film so that ends of the insulation film are located in the groove.
